(19) United States
(12) Patent Application Publication
(10) Pub. No.: US 2016/0237555 A1
(43) Pub. Date: Aug. 18, 2016

(54) Multi-Magnetron Arrangement

(71) Applicant: MEYER BURGER (GERMANY) AG, Hohenstein-Emstthal (DE)

(72) Inventors: Joachim Mai, Nobitz (DE); Dirk Rost, Callenberg (DE); Rainer Baumgärtner, Limbach-Oberfrohna (DE)

(21) Appl. No.: 15/031,721

(22) PCT Filed: Oct. 23, 2014
(86) PCT No.: PCT/EP2014/072762

§ 371 Date: Apr. 23, 2016

(30) Foreign Application Priority Data
Oct. 24, 2013 (DE) 10 2013 221 680.7

(51) Int. Cl. C23C 14/35; H01J 37/34; H01L 21/677

(52) U.S. Cl. CPC C23C 14/35; H01L 21/6776; H01J 37/3435; H01J 37/3405; H01J 37/3458; H01J 37/3455; H01J 37/3479

(57) ABSTRACT

A method and a device for carrying out the method for processing surfaces of workpieces, preferably of large substrates, are presented. The intent is to arrange the processing devices on the casing of a drum-type carrier in a vacuum chamber. The workpiece is transported over the drum and optionally made to rotate. The drum-type carriers is rotated in such a way that the intended processing device is turned towards the workpiece and can process it. The surface section to be processed can be selected via translation and rotation.

### CROSS REFERENCE TO RELATED APPLICATIONS

This application is the U.S. national stage of International Application No. PCT/EP2014/072762, filed on Oct. 23, 2014, and claims the priority thereof. The international application claims the priority of German Application No. DE 102013221680.7 filed on Oct. 24, 2013; all applications are incorporated by reference herein in their entirety.

### BACKGROUND

Various methods are used when processing surfaces, for instance when coats of thin layers are applied or the surface is removed. Methods of physical or chemical vapor deposition are of particular importance with regard to coating. Sputtering, in which particles are removed from a target material via particle bombardment and then deposited on the surface to be coated, is frequently used for coating surfaces in the semiconductor, solar-cell and optical industries. Ion-beam etching or plasma etching methods, as examples, are used for surface removal.

The above-mentioned methods of surface processing customarily take place in a vacuum or in specific gas atmospheres. It is problematic under these conditions when the technology requires frequently changing processing methods or methods that only involve a low level of continuity of processing quality. Normally, the substrates to be processed in cases of this type are moved through a gate from one processing machine into a subsequent processing machine in which the subsequent processing step is then carried out. Movement processes of this type through a gate always involve handling problems, in particular when there are very large and heavy substrates, or problems based on the vacuum conditions.

In particular, when surfaces are coated with thin layers, the quality and uniformity of these layers forming the coating are important. More than 1000 layers are applied in part in coatings in modern applications. The coating technology has to therefore be carried out with the highest possible quality and repeatability. The structuring of these coating layers, in particular the measurement and rework of layers required within the framework of quality assurance, is to also be realized in a reliable way.

Ion-supported technology is also used both for the application and for the rework of the layers. It is therefore frequently possible to carry out technologies that require analog vacuum conditions (pressure, temperature, possibly certain gas components) in a common vacuum chamber. So-called wafer carousels (for instance U.S. Pat. No. 6,949,177 B2) are known from the semiconductor industry in which similar wafers are transported in a rotatory manner from one processing station to the next. Systems of that type are very effective when the processing of a multitude of similar, relatively small substrates is involved. They are hardly suitable, however, when large substrates have to be processed. The suitability of these devices is also questionable for individual production or production in small series.

### SUMMARY

A method and a device for carrying out the method for processing surfaces of workpieces, preferably of large substrates, are presented. The intent is to arrange the processing devices on the casing of a drum-type carrier in a vacuum chamber. The workpiece is transported over the drum and optionally made to rotate. The drum-type carriers is rotated in such a way that the intended processing device is turned towards the workpiece and can process it. The surface section to be processed can be selected via translation and rotation.

### DETAILED DESCRIPTION

The problem of proposing a design that is suitable for processing large substrates, in particular, using ion-beam and plasma technologies therefore arises.

The problem is solved as per the invention with the device according to claim 1. A method using the device as per the invention is described in claim 13. Advantageous embodiments are presented in the dependent sub-claims.

At least the following steps are carried out in the method as per the invention for processing surfaces of workpieces, in particular substrates with several processing layers in a vacuum chamber with a carrier drum (preferably a cylindrical body) that has a number of processing devices:
Holding the workpiece in the vacuum chamber on a suspension element on a transport device with a main axis of motion,
Rotating the carrier drum until the processing device to be used reaches the operating position and becomes the active processing device,
Moving the workpiece along the main axis at a slight distance to the active processing device, wherein a first processing technology is applied to the workpiece,
Repeating the steps of rotating the carrier drum and moving the workpiece with the application of the next processing technology until the intended surface condition is achieved.

The processing system has a large vacuum chamber, preferably with an air lock in front of it. The workpiece preferably involves a large substrate. Workpieces that weigh more than 10 kg during the processing, preferably more than 100 kg, are regarded as large substrates. The workpiece is preferably attached to a holding element that makes the workpiece accessible to an uptake by a machine during the processing. When movement of the workpiece is discussed below, this refers to the movement of the workpiece via this holding element as a preference. The design of holding elements of this type is known in the prior art. The work piece is fed into the vacuum chamber (preferably through an air lock). In the vacuum chamber, it is preferably transported, hanging on a suspension element, in horizontal and vertical directions. The suspension element is preferably moved via a linear motor. Preferred supported movement is also possible, however, in which the carrier drum is arranged above the workpiece or on the side of the workpiece. The suspension element is preferably fastened in a movable and drivable way on a horizontal carrier that sets the direction of the main axis. The workpiece can preferably also be rotated around a vertical axis during the horizontal movement. The rotation of the workpiece is preferably realized via a motor that is likewise integrated into the suspension element on the transport device. This motor (including an optional transmission and auxiliary devices) is preferably arranged in a gas-tight enclosure. This gas-tight enclosure preferably has one (optionally two) supply units running in parallel with the main axis of motion. As a special preference, the supply unit or supply units are realized in the form of rigid, hollow rods (tubes) that lead through and out of a vacuum feedthrough (preferably a bellows-type membrane seal) in the wall of the vacuum chamber. The supply units can be moved along their longitudinal axis in the vacuum feedthrough. They can follow the movement of the suspension element on the transport device along the main axis of movement in this way or, as the case may be, this movement can also be initiated and controlled via the rigid supply units. A suitable linear drive unit is provided for this on the outside of the vacuum chamber. Transfers of energy, data and process utilities can advantageously be made through the inner hollow area of the supply unit. In a further preferred embodiment, a motor for bringing about the rotation of the workpiece is not provided in the suspension element, but instead merely a gearbox that transfers rotary movement provided through the interior of the of the supply unit via a shaft or a hydraulic connection.

The carrier drum is preferably arranged below the suspended workpiece. The carrier drum is preferably designed in the form of a cylindrical, hollow body with a casing and two top faces. The workpiece is moved along the main axis over the active processing device in the operating position and is thereby processed. In a preferred embodiment, the speed along the main axis is varied to create processing profiles. In a further preferred embodiment, the distance at which the workpiece is moved past the carrier drum varies in dependence upon the processing device in the operating position. If uniform processing is required, the workpiece to be processed is optionally put into rotation in an advantageous manner. The rotary speed can be varied or kept constant as required.

The processing devices are either arranged on or in the casing here, or they are arranged on or in a top face of the carrier drum. The carrier drum has a central axis around which it is rotated in order to put the desired processing device into the operating position. If the processing devices are arranged in the casing, the central axis of the carrier drum is aligned in such a way that it is in a plane that is perpendicular to the axis of rotation of the workpiece. If the processing devices are arranged in a top face of the carrier drum, the central axis of the carrier drum will preferably run in parallel with the axis of rotation of the workpiece. In addition to the preferred embodiments, any position of the carrier drum with respect to the workpiece is possible in principle with an arrangement of the carrier drum below or above the workpiece.

Similar or different processing devices can be arranged as processing devices on the carrier drum. Different ion-beam sources, plasma sources and magnetrons can be arranged, as examples, on the drum. Both processing devices for applying material, for instance magnetrons, and processing devices for removing material, for instance with ion-beam etching or plasma etching, can be jointly arranged on a carrier drum in a preferred embodiment. Processing devices in this context are also understood to mean measurement or monitoring apparatus that is suitable for investigating the surface condition of the workpiece and, for instance, for determining the requirements or success of the processing. Optical measurement devices such as microscopes, spectroscopes, interferometers or laser measurement devices, as examples, are devices of that type. The carrier drum will preferably have at least two or, as a further preference, three, four, five or six processing devices. Eight processing devices are also preferred, however. The maximum number of processing devices is only established by the spatial and technical boundary conditions. As a very special preference, all of the processing devices are magnetrons.

The carrier drum is rotatably supported on at least one side, preferably on both sides; the support preferably has a hollow shaft on at least one side through which flexible supply lines can be routed to supply electrical power, provide a data connection, supply gas and, if necessary, provide a high-frequency feed for the processing devices. In a preferred embodiment, one or more of the processing devices also have their own control possibilities available both with regard to the operating process and with regard to the spatial orientation. This preferably applies to ion-beam sources and measurement devices that can be provided, for example, with their own gimbal-mounted suspension element or a suspension element operating in a similar fashion. The carrier drum is rotated via a drive unit in such a way that the intended processing devices is turned towards the surface to be processed. The processing device is therefore in the operating position.

In a preferred embodiment, the vacuum chamber has one or more further processing, measurement or inspection devices via which the workpiece can be positioned and optionally rotated. These processing, measurement or inspection devices involve, for instance, ion-beam sources, electrical or optical microscopes, electron-beam sources, cameras etc. These devices are not arranged on the carrier drum.

The method as per the invention will be explained below with an example of the preferred use of magnetrons as the processing devices and a substrate as the workpiece.

Magnetrons or simple cathode sputtering sources are frequently used to generate the particles that remove particles from a target material. The magnetron or cathode sputtering source has a cathode that is attached to the material to be bombarded. This is preferably done with the aid of a so-called target. Whereas only an electric field is created at the cathode in the case of simple cathode sputtering sources, an additional magnetic field is brought about behind the cathode plate in the case of the magnetron. A plasma is created in the gas-filled space in front of the cathode when an electric field is created. The ions of the plasma that are created are accelerated in the electric field and remove particles from a target material (target) that are deposited on the surface to be coated. DC voltages, pulsed DC voltages or low-frequency or high-frequency alternating fields are possibilities as electrical fields. Noble gases such as argon or krypton are preferably used as gases. Other gases can also be added to the gas, though, that react with the surface to be coated with the particles that are being deposited and thereby form compound layers (reactive sputtering). As an example, a layer of TiO₂ can be created on the surface to be coated via the use of titanium as the target material and the addition of O₂ to the gas.

When a magnetron is used, it is slowly exhausted because of the continued removal of the target material or, as the case may be, the characteristics of the sputtering process change because the geometry of the magnetron has changed in this way. Consequently, a replacement of the magnetron or at least the replacement of the target material would be necessary during processing.

There are a number of approaches for handling this problem in the prior art. U.S. Pat. Nos. 4,356,073 and 5,213,672 describe approaches of this type. Rotating target material is used in the process. This ensures that the target material is evenly removed over the entire rotation body and that local overheating does not come about. This approach does in fact ensure an increase in the useful life of the target, but it can only delay final exhaustion.

EP 0 543 844 B1 presents a design in which the entire magnetron rotates. The substrate to be coated is moved past the cathode of the magnetron and coated in the process. The design of a rotating magnetron was perfected in DE 10 2009 053 756.2, for example, where periodically occurring, design-related fluctuations based on slight irregularities in the cylindrical form of the magnetron are to be balanced out with a variation of the target voltage. The rotating magnetrons obviously also do not have a sufficient useful target life and process stability.

The method as per the invention provides, within the framework of the preferred embodiment here, for the use of a plurality of magnetrons that are arranged on the rotatable cylindrical carrier drum; at least one magnetron is started up and put into an operating position for this, as the active magnetron, relative to an object to be coated. The object to be processed (the substrate) is preferably moved with respect to the magnetron in such a way that the entire area that is supposed to get a coating gets one. If a plurality of coatings are required, a corresponding plurality of coating processes will be advantageously carried out. The coating processes can be carried out with one and the same magnetron in the process, or the active magnetron is replaced after the conclusion of a coating process. The magnetrons can be advantageously exchanged in that way before their coating characteristics change or the target material is exhausted. Since the carrier drum is housed in a vacuum together with the substrate to be coated, ventilation or air-lock processes are not necessary when the active magnetron is changed. So the coating process, even of large substrates, can be concluded before it is necessary to replace the target. In addition to a significant acceleration of the coating process, this also leads to an increase in quality because the coating conditions in the vacuum do not change.

Since the carrier drum is exclusively equipped with magnetrons in this example, it will be called a magnetron drum below. A first preferred embodiment provides for a magnetron drum that has a horizontally supported cylindrical body. The magnetrons are preferably rod-shaped and in parallel with the axis of rotation of the cylindrical body and arranged on or in its casing. The rod-shaped magnetrons are at least as long as the maximum width to be coated of the substrate to be coated. The magnetrons preferably have rod-shaped target material here that can preferably be manipulated separately from the magnetron, in particular exchanged, as a component that has the approximate overall length of the magnetron. The magnetrons can be identical with regard to both the design and the target material, or they can be different, for instance having different target materials, to be able to create coating layers made of different materials. Further magnetron designs, preferably rotating linear magnetrons, preferably with tube cathodes, are also possible. The magnetron drum is rotatably supported on at least one side, preferably on both sides; the support preferably has a hollow shaft on at least one side through which flexible supply lines can be arranged to supply electrical power, supply gas and, if necessary, provide a high-frequency feed for the magnetrons. The magnetron drum is rotated via a drive unit in such a way that the intended magnetron is turned towards the surface to be coated. The magnetron is therefore in the operating position.

A preferred embodiment provides for the capability of also starting up magnetrons that are not in the operating position so that a break-in process up to stable operation can be carried out. Studies have shown that the break-in process of the magnetrons is dependent upon the pressure conditions and also upon the geometric conditions, in particular the distance of the area to be coated to the magnetron. To bring the magnetrons up to an operating state corresponding to the operating state in the operating position, the invention envisages that the distance to the enclosure (wall) of the magnetron drum of the magnetrons that are not in the operating position will correspond to the distance that the magnetron will have in the operating position to the surface of the substrate to be coated. The deviation of the distance of the magnetron that is not in the operating position to the distance that the magnetron in the operating position has to the surface of the substrate to be coated is preferably less than 25%, with a special preference for less than 15% and a very special preference for less than 5%. Since the same geometric conditions exist both for magnetrons that are in the operating position and for those in positions that are not operating positions, a break-in process is possible that stabilizes the magnetrons in the operating state, which is favorable for a coating operation. In an especially preferred embodiment, the vacuum conditions for the magnetrons outside of the operating position are likewise matched to those in the operating position. The enclosure of the magnetron has one or more gas exhaust systems for this that extract the gas given off by the magnetrons outside of the operating position and the vacuum conditions are matched in that way to those in the vacuum chamber in which the substrate is coated. The gas exhaust systems are arranged in such a way that the gas flow corresponds to the gas flow that acts upon the magnetron in the operating position. In particular, the pressure difference between the vacuum chamber and the enclosure of the magnetron is less than 10%, less than 5% as a special preference and less than 2.5% as a very special preference.

In a preferred embodiment, each magnetron has its own fixed or detachable supply lines. In a further preferred embodiment, there are one or more automatic connections to supply lines via which both the magnetron that moved into the operating position and also magnetrons in other positions can be connected in a detachable way.

As a preference, the rotary direction of the magnetron drum is always chosen in such a way that a twisting of supply lines is minimized during the positioning of the magnetron.

The horizontally supported magnetron drum is preferably used in a system for coating large-sized substrates. The system has a large vacuum chamber for this with an air lock in front of it. The substrate to be processed is fed into the vacuum chamber through the air lock. The feed-in preferably takes place on the side, directly under the suspension element, so that only a slight push is necessary to connect the workpiece to the suspension element. In the vacuum chamber, it is preferably transported, hanging on the suspension element, in horizontal and optionally vertical directions. The suspension element is fastened in a movable and drivable way to a horizontal carrier. The substrate can preferably also be rotated around a vertical axis during the horizontal movement. The magnetron drum is preferably arranged below the hanging substrate. The component is moved along the main axis over the active magnetron in the operating position and thereby receives a coating layer. In a preferred embodiment, the speed along the main axis is varied to create defined coating profiles. If uniform coating layers are required, the substrate to be processed is optionally made to rotate in an advantageous way. The rotary speed can be varied or kept constant as required.

Once a layer has been completely applied, the direction of motion along the main axis is reversed and the substrate is coated once again if necessary. The magnetron that was previously in the operating position can be used for this or, if the target material has to be changed or if a different coating material is required, a different magnetron can be put into the operating position via rotation of the magnetron drum. The selected magnetron can already be started up beforehand or can be first started up in the operating position. A further coating layer can now be provided via movement along the main axis and optionally via rotation of the substrate. This is continued until the desired layer structure of the coating is achieved or until a functional magnetron with the required layer material is no longer available. The substrate is output out of the vacuum chamber through an air lock when the coating process is complete.

In a preferred embodiment, the carrier drum is arranged in an enclosure. The drum has an opening for the intended processing device through which it can process the surface of the workpiece. It has been show, in particular when magnetrons are used, that the existence of the workpiece in front of the magnetron can lead to different plasma characteristics. An effort is made, however, to always have a stable plasma available for processing. The enclosure is therefore preferably arranged at a distance to the plasma sources that corresponds to that of the workpiece in the processing position. There is only an adjustment of the distance of the enclosure in the area of the opening for the intended processing device, so the processing devices can be brought into the processing position without making contact with the enclosure, but the workpiece can also be moved without making contact with the enclosure. The enclosure preferably has its own gas exhaust system. This gas exhaust system ensures that gas-pressure conditions or gas compositions that have to later be achieved in the operating position prevail in the enclosure and in front of the respective magnetrons. Since the magnetrons are also in operation when they are not in the processing position, in order to be in a stable operating state, the gas that is used (usually argon) is to be extracted in a defined manner. This is also preferably realized by the gas exhaust system. The enclosure also preferably has the gas-supply devices. A “cross flow” known to persons skilled in the art can advantageously be realized over each magnetron in that way. The gas extraction and supply can take place through the hollow axle of the carrier drum, for instance. Other preferred embodiments provide for the carrier drum to have openings in one or both of their cylindrical faces that are congruent in the processing positions with suction openings of the gas exhaust system and that are covered up by the bearings of the carrier drum during the rotation process. An analogous approach can be taken with regard to the gas supply.

Adjustment devices (match boxes) are usually used to match the output between the HF generator and the magnetron when high-frequency alternating voltages are utilized. They are preferably located in the carrier drum. This advantageously shortens the length of the required transmission lines to the coupling point or the several coupling points of each magnetron. The match boxes for this are preferably arranged in their own vacuum-tight containers. The containers of the match boxes can be filled with air or advantageously with a protective gas (for instance dry nitrogen).

In a simple, preferred embodiment, the processing devices, for instance the magnetrons or more specifically their target material, are replaced during the standstill periods of the device. The vacuum chamber preferably has a maintenance door for that. A further preferred embodiment provides for the possibility, however, of replacing the magnetron whose target material is exhausted in situ. To this end, the magnetron drum is rotated into a position in which the magnetron to be maintained is rotated out of the operating position into a replacement position. The replacement position of the magnetron drum is preferably opposite the operating position. It is possible in this position to dock an air-lock device on the magnetron drum that permits the replacement of the target material. A first embodiment provides for the exhausted target material to be pulled out at the face of the magnetron drum, put into intermediate storage in the air lock and then removed. The new target material is likewise brought in through the air lock, put into the magnetron from the face side and anchored there. The fact that the cross-section of the air-lock opening to be covered is small because the air-lock opening is only somewhat larger than the cross-section of the rod-shaped target material is advantageous with regard to this solution. The target material is preferably done in an automated fashion or with a manipulator that handles the target material in the vacuum.

A further preferred embodiment provides for an air-lock opening that removes the target material perpendicularly to the casing of the magnetron drum. The fact that the system width is not increased by an air-lock device connected beside it is advantageous in connection with this. The target material is also preferably done here in an automated fashion or with a manipulator that handles the target material in the vacuum.

Another preferred embodiment provides for the entire rod-shaped magnetron to be replaced instead of the target material. This embodiment is especially advantageous in connection with the use of supply lines that are connected via automatic connectors to the magnetron in the operating position. A further preferred embodiment provides for the supply lines to be integrated into the faces of the magnetron drum and to be brought there to the magnetrons. A detachable connection to the magnetrons preferably exists in the faces of the magnetron drum.

An advantageous method of operation provides for a magnetron with exhausted target material to be in the replacement position because of the position of the magnetron drum during the operation of the magnetron in the operation position. The target material, or the magnetron with exhausted target material, can then be replaced without interruption of the coating operation. Further required maintenance work on magnetrons of that type is likewise possible.

An especially preferred embodiment provides for the existence of not just one air lock, but instead multiple air locks. These air locks preferably correspond to the positions taken by the magnetrons that are not in the operating position during the coating. Multiple magnetrons can be simultaneously provided with new target material or maintained in that way.

A further preferred embodiment provides for a magnetron drum that has a vertically supported cylindrical body. The magnetrons are arranged in a standing fashion in the form of small, round sputter magnetrons in the magnetron drum. “Round” means here that the magnetrons have a cup-shaped design and are essentially circular in the horizontal cross-section. The coating material leaves at the top from the top face of the magnetron cylinder. The magnetron or magnetrons that are in operation are released by apertures so that the coating material can be output. The other magnetrons are covered by screens. A rotatably mounted screen exists that only releases the one magnetron that is in operation. Unreleased magnetrons can already advantageously be in operation, however, in order to bring about a stabile operating point until they are used. The magnetron drum is rotated around its vertical axis to bring the magnetron that is to be called up for the coating process into the required position. Further rotation can optionally take place during the processing.

The workpiece is preferably, just as in the case of the use of a horizontal magnetron drum, moved past the magnetron along a main axis with optional rotation. The corresponding parameters for translatory and rotary movement of the workpiece were calculated in advance. The fact that layer-thickness profiles can be created on the workpiece that do not have to be rotationally symmetric is advantageous with regard to the vertical magnetron drum. Profiles of that type are advantageous, as an example, in the creation of free-form surfaces or spherical sections with the desired layer-thickness gradients.

The magnetron axle is preferably hollow so that the lines to the magnetrons are also connected through the axle here.

The exhaustion and the replacement of the target material required because of that are also a limiting parameter with regard to the shorter, round magnetrons used here. A preferred embodiment therefore provides for the capability of exchanging the magnetrons from the top face of the magnetron drum that is turned away from the screen. The lines for electrical power, gas and high frequency are connected to the magnetrons in a detachable way for that. If necessary, the lines are detached and an air-lock construction is moved to the magnetron. The magnetron is then removed in its entirety from the magnetron drum, and a replacement magnetron is inserted. After that, the lines are attached again.

The entire system (vacuum system) and the coating process are preferably controlled via a data-processing unit. To this end, sensors exist in the system that also determine, in addition to the position and state of the workpiece, the information regarding the position, operation and wear of the target material and magnetrons, as well as the state of the vacuum in the system etc. These sensors transmit the collected data in a wireless or wired fashion to the data-processing unit, which then evaluates this data and includes the data in the control decisions of the vacuum system. The exchange of the target material and the magnetrons is also controlled, if necessary, by the data-processing unit (or by a further data-processing unit intended to be used for that). In particular, the coating process is calculated in advance (modeled) in the data-processing unit of the vacuum system or in a different data-processing unit, in order to determine the characteristic data such as the required layer thicknesses, the number of layers, the coating times, the distances between the workpiece and the magnetron in the operating position, the feed rate and, if applicable, the rotation speed etc. This data is then, if the calculations have not already taken place there, transmitted to the data-processing unit of the vacuum chamber.

### BRIEF DESCRIPTION OF THE DRAWINGS

FIG. 1: Schematic diagram of the arrangement as per the invention with a magnetron drum with a horizontal axis and a vertical air-lock feed.

FIG. 2: Schematic diagram of the arrangement as per the invention with a magnetron drum with a vertical axis and a vertical air-lock feed.

FIG. 3: Schematic diagram of the representation of the invention with an enclosed magnetron drum and a horizontal air-lock feed.

FIG. 4a to FIG. 4f: Schematic diagram of embodiments of the magnetron drum with an enclosure. The distance relationships of the magnetrons that are not in the operating position with respect to the enclosure and of the magnetron that is in the operating position with respect to the substrate are not shown in a realistic fashion.

FIG. 5: Schematic diagram of the device as per the invention with a supply unit and linear motor in the interior of the vacuum chamber.

FIG. 6: Schematic diagram of the device as per the invention with a supply unit and linear motor outside of the vacuum chamber.

FIG. 7: Schematic diagram of the device as per the invention with a supply unit in a top view and with an air lock arranged on the side.

FIG. 8 schematically shows the operating conditions of the magnetron that is not in the operating position with respect to the enclosure and of the magnetron that is in the operating position with respect to the substrate. The two distances are identical or nearly identical as per the invention.

### DETAILED DESCRIPTION OF THE PREFERRED EMBODIMENTS

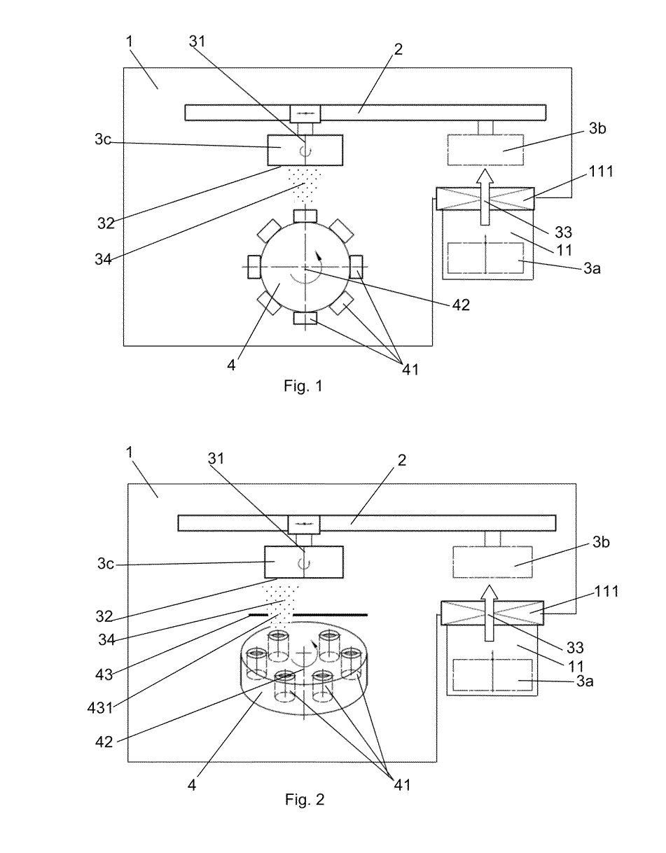

FIG. 1 shows a schematic diagram of the arrangement as per the invention with a magnetron drum with a horizontal axis (42). In particular, the workpiece is shown in three positions 3a, 3b, 3c. These positions are reached one after the other. This consequently does not involve three workpieces that are processed at the same time.

FIG. 2 shows a schematic diagram of the arrangement as per the invention with a magnetron drum with a vertical axis (42). In particular, the workpiece is shown in three positions 3a, 3b, 3c. These positions are reached one after the other. This consequently does not involve three workpieces that are processed at the same time. The embodiment of FIG. 2 of the device as per the invention corresponds in terms of its parameters to the first example. The magnetron (41) that carries out the next coating process is moved into the operating position around the vertical axis (42), and the aperture (43) is simultaneously rotated in such a way that it releases its opening for particles of the sputtered target material of the magnetron (41) in the operating position.

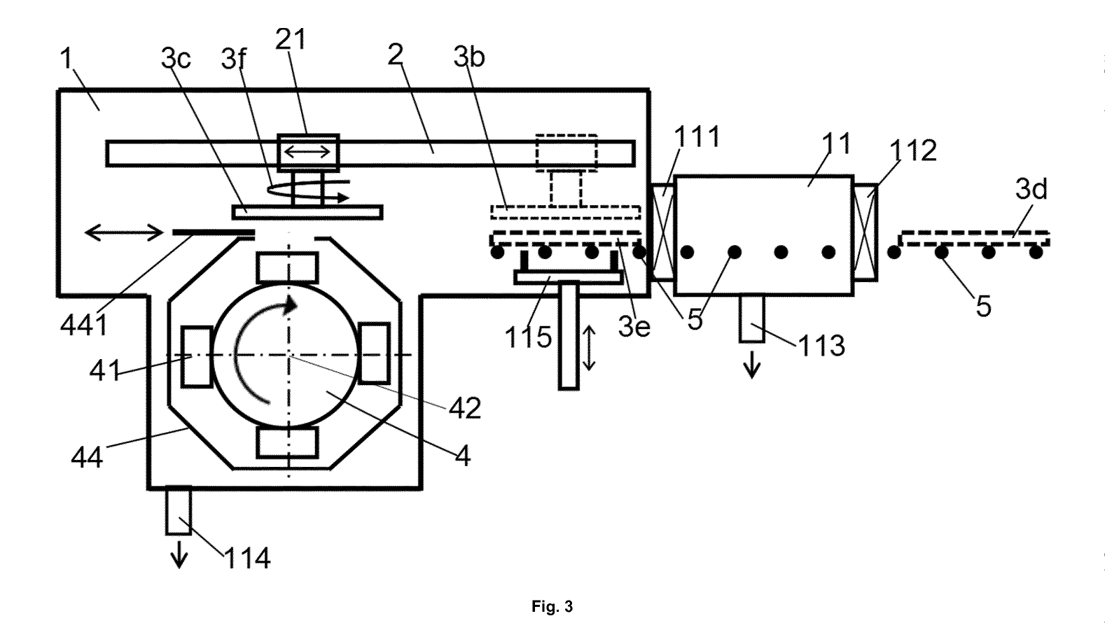

The example in FIG. 3 of the device as per the invention has a vacuum chamber (1) in which the main axis (2) is formed by a carrier with a length of 4000 mm. The width of the vacuum chamber (1) is 2000 mm, in order to be able to accommodate workpieces (3a, 3b, 3c) with a diameter of up to 1500 mm. A suspension element (21) is arranged on the carriers (2) that can accommodate loads of up to 1000 kg. This suspension element also makes it possible to cause the workpiece (3c) to rotate around the axis (31) at up to 3 Hz. In order to also be able to process workpieces with different dimensions, they are put into a uniform carrier system (holder) outside of the device and they consequently form a new common workpiece. The workpiece and carrier system are jointly accommodated by the suspension element (21) inside of the vacuum chamber. The magnetron drum (4) has four planar magnetrons (41) with a length of 1700 mm distributed equidistantly over the casing. The diameter of the magnetron drum (4) is 1000 mm. A mid-range operating pressure of approx. 2×10⁻³ mbar is set in the vacuum chamber for the operation of the magnetron. The operating pressure can be typically varied between approx. 2×10⁻⁴ mbar and approx. 2×10⁻² mbar, though. The vacuum chamber can be evacuated down to a base pressure of <1×10⁻⁷ mbar to maintain clean operating conditions within the vacuum chamber and to avoid contamination from the atmosphere. The vacuum chamber can advantageously be baked out or tempered for that.

The air lock (11) has an opening width of 2000 mm×2000 mm with a height of 800 mm. The workpiece (3a) is moved into the vacuum chamber on the rollers of the transport device (5) in the air lock (11) that is open in the direction of the vacuum (33), lifted by the lifting device (115) and automatically coupled to the suspension element. After that, the workpiece (3c) is moved along the main axis of the transport device (2) via a linear drive unit and made to rotate. The magnetrons (41) of the magnetron drum (4) were already started up before the actual processing of the workpiece starts. The magnetron drum is surrounded by an enclosure (44) that has an operating opening with a movable cover (441) in the direction of the workpiece. The enclosure (44) of the magnetron drum (4) has the same distance to the magnetron (41) that the workpiece (3c) will have above the magnetron (41) in the operating position. The magnetrons (41) can therefore already achieve a stable plasma state and do not have to be started up in the operating position. At the same time, the magnetron (41) that contains the material to be applied as the target material is moved into the operating position for the feed-in of the workpiece. Since the magnetrons (41) have already been started up, the magnetron in the operating position immediately achieves stable operation and the workpiece (3c) rotating at 2.00 min⁻¹ is moved past the magnetron (41) at a defined speed profile and at a distance of 60 mm from the target surface of the magnetron. In so doing, the first coating layer is deposited on the surface (32) of the workpiece (3c) to be processed. Typical speed profiles contain speed changes between 0.1 mm/s and 30 mm/s. Linear-motor drive systems are preferably used to be able to achieve these speed changes. The distance between the workpiece and the target surface can be set from approx. 50 mm to approx. 100 mm. As soon as the workpiece (3c) has completely moved over the magnetron (41), its movement is slowed down and reversed. At the same time, the magnetron drum (4) is rotated around its axis (42) in such a way that the next magnetron (41) that has been started up will now reach the operating position. The next magnetron (41) now applies the subsequent coating layer in an analogous fashion while the rotating workpiece (3c) moves over it.

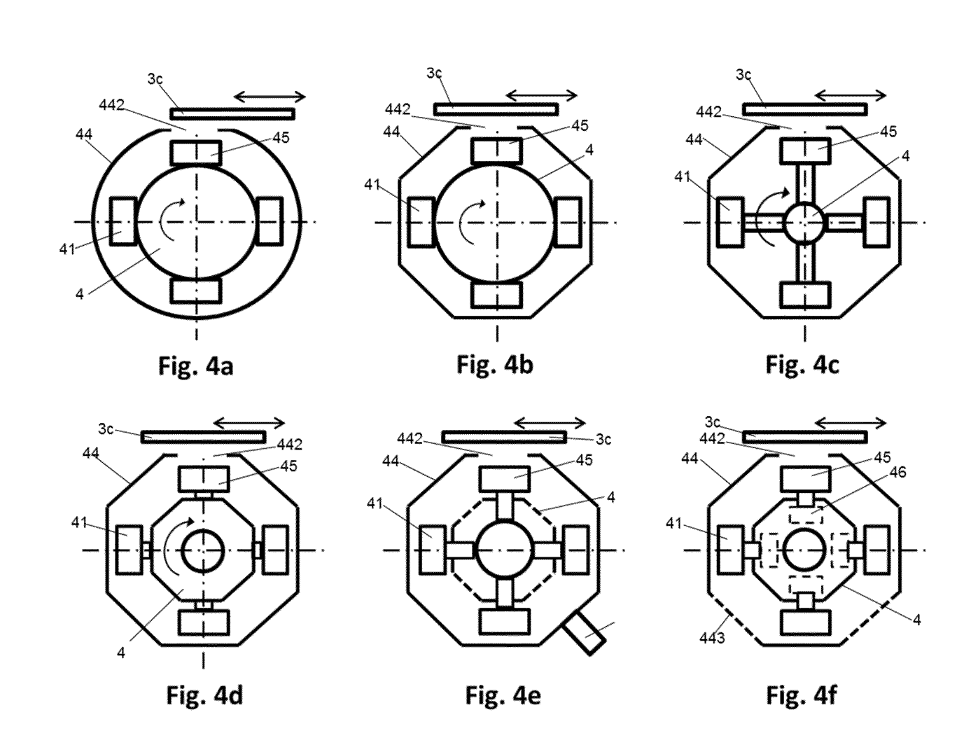

FIG. 4a to FIG. 4F schematically show various design variants of the magnetron drum (4) and the accompanying enclosure (44). A simple embodiment with four magnetrons (41) on the magnetron drum (4) is shown in FIG. 4a. The workpiece (3c) is moved above the operating opening (442) of the enclosure and of the magnetron in the operating position (45). The enclosure (44) has a circular cross-section here.

The enclosure has an octagonal design in FIG. 4b. Each magnetron (41)—four magnetrons (41) are shown, up to eight would be useful here—is opposite a flat section of the enclosure (44). This is especially advantageous because the stabilization of the plasma takes place here in a geometry that particularly close to the geometry that is to be expected in the operating position.

The magnetron drum (4) is designed as an axle with arms that support the magnetrons (41) in FIG. 4c.

The embodiment according to FIG. 4d has a magnetron drum (4) that likewise has an octagonal design. Together with the octagonal enclosure (44), an advantageous geometry arises in that way in which the surfaces of the magnetron drum (4) are opposite the surfaces of the enclosure (44). Surfaces that are not occupied with a magnetron (41) in the depiction are also preferably prepared for the attachment of a processing device so that a reaction is possible within the framework of a conversion to different technological processes.

FIG. 4e shows an embodiment in which the magnetron drum (4) is pierced so that a gas exhaust system, which is realized through the hollow central axle of the magnetron drum (4), will suction the gas out of the intermediate space between the magnetron drum (4) and the enclosure (44). Thus, there is an advantageous balancing of the pressure conditions with respect to those in the vacuum chamber.

The embodiment according to FIG. 4f schematically shows the arrangement of the match boxes (46) of the magnetrons (41) in the interior of the magnetron drum (4). The enclosure (44) in this embodiment has gas suction openings (443) that make it possible to suction the gas out of the intermediate space between the magnetron drum (4) and enclosure (44). It is ensured in this way that the vacuum conditions in the intermediate space will come close to those in the vacuum chamber (1).

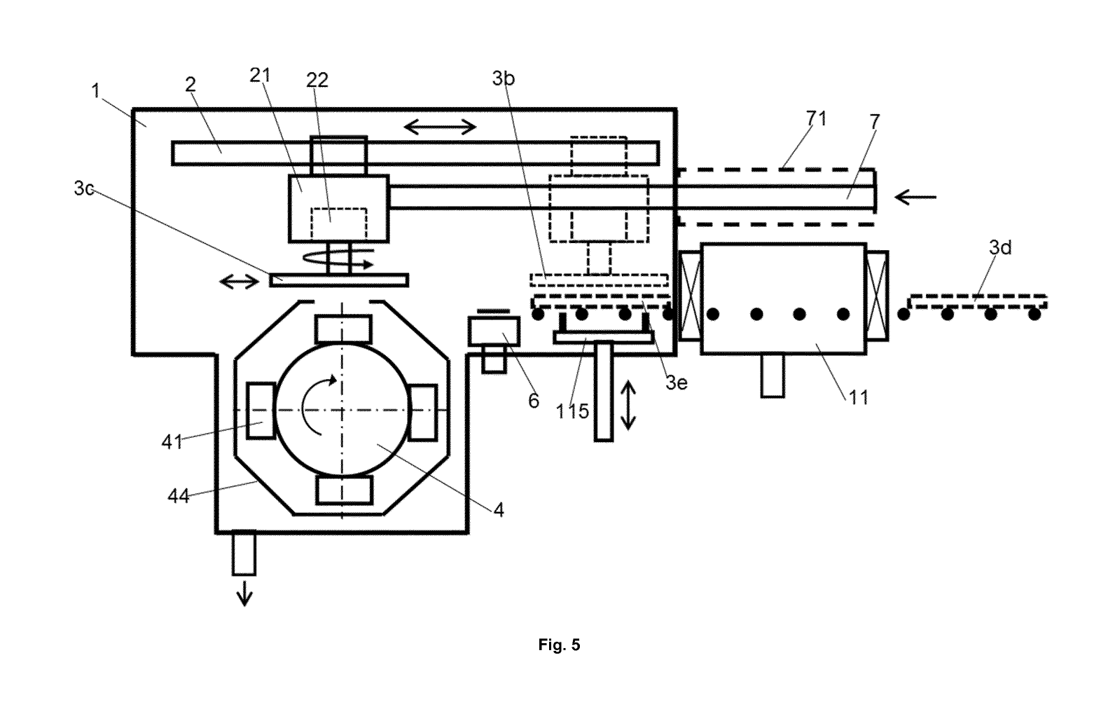

The embodiment according to FIG. 5 schematically represents the supply unit (7). It is hollow in its interior and permits the routing of supply and data lines to the suspension element (21). The supply unit (7) follows the movement of the suspension element (21) along the transport device with the main axis (2). The supply unit is provided with a bellows-type membrane seal (71) that follows the movement to be able to ensure vacuum-tight conditions during the movement. The motor (22) is arranged in a vacuum-tight enclosure in the suspension element (21) that realizes the rotary movement of the workpiece (3c). An ion source (6) that makes further processing of the workpiece (3c) possible is shown next to the lifting device (115) in this embodiment. The workpiece (3c) can be positioned above the ion source (6) for this. The rotary movement and the translatory movement along the main axis (2) make it possible to process any arbitrary point on the side of the workpiece (3c) turned towards the ion source. Other processing or analysis devices (for instance microscopes) can also be put there in place of the ion source (6).

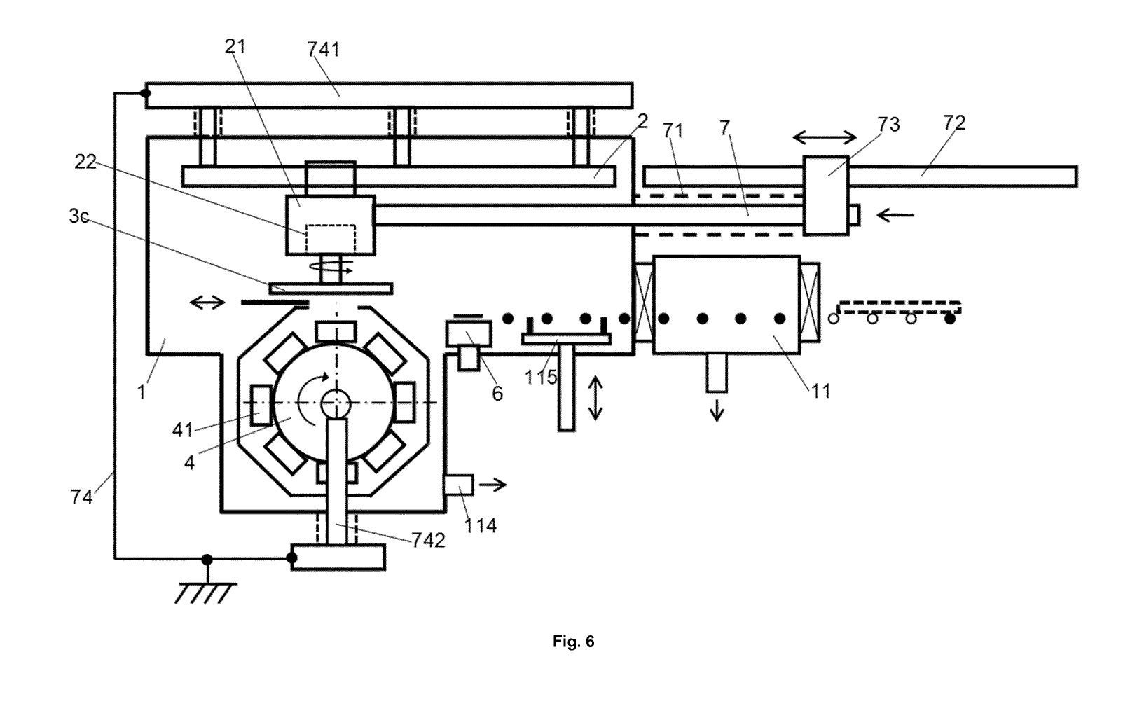

FIG. 6 schematically shows how the device as per the invention can be realized; the carrier of the movable parts is mechanically decoupled from the vacuum chamber (1). The reinforcement system (74) connects, via an exterior reinforcement part (741), the transport device with the main axis (2) to the holder of the magnetron drum (742). This reinforcement system (74) holds the transport device with the main axis (2) over the membrane-bellow through-holes via the reinforcement part (741). The holder (742) of the magnetron drum (4) is also realized via membrane-bellow through-holes. A mechanical decoupling of the vacuum chamber and the movement system is therefore possible, and the required precision of the substrate movement is achieved.

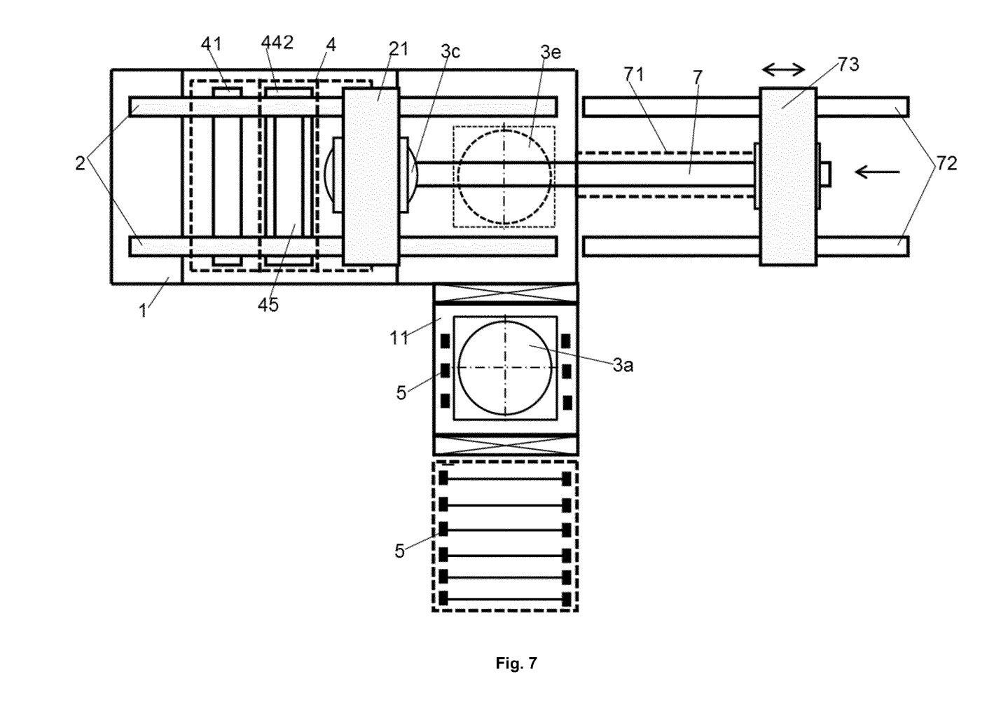

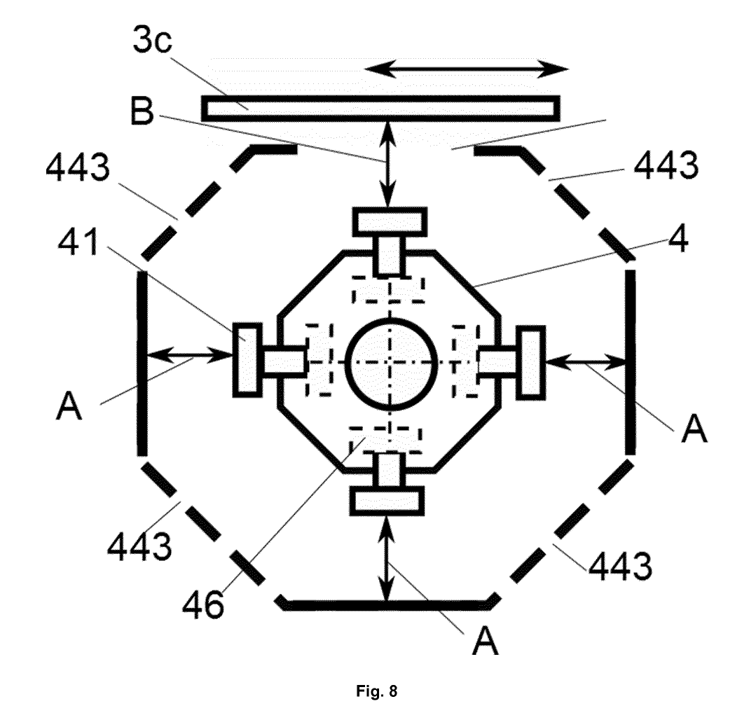

FIG. 7 schematically show a device as per the invention in a top view in which the air lock (11) is realized in the form of a lateral add-on. The carrier device with the main axis (2) is designed in the form of a double carrier device here. The suspension element (21) moves on the two parallel carriers (2) along the main axis, which runs in the center here between the two carriers (2) and in parallel with them (not shown). A magnetron (41) in a waiting position (actually hidden, but visible here in a through-hole) and a magnetron (45) in the operating position are shown. The magnetron (45) in the operating position can process the workpiece (3c) when it is moved over the operating opening (442) of the enclosure. The movement of the drive device (73) of the supply unit is synchronized with the movement of the suspension element (21). This drive device is also arranged on a carrier device designed in the form of a double carrier device (72) and movable in the direction of the main axis. The lateral arrangement of the air lock (11) makes it possible to move the workpieces (3d) into or out of the air lock (11) with being obstructed by the carrier device (72) of the supply unit (7). The workpieces are delivered and picked up between the atmosphere area and the handover or takeover position in the process chamber with a so-called transport carrier. The transport carrier is adapted for different workpiece dimensions here to the selected transport system and carrier system. A roller transport system is shown as an example of the transport system in FIG. 7.

FIG. 8 schematically shows an embodiment as per the invention that corresponds to that of FIG. 4f. To illustrate the inventive idea of adapting the conditions that exist for the magnetrons outside of the operating position to those of the magnetron in the operating position, the distances (A) of the magnetron outside of the operating position with respect to the enclosure (44) and the distance (B) of the magnetron in the operating position with respect to the substrate (3c) were drawn into FIG. 8. The distance (A) is supposed to be equal or nearly equal to the distance (B). To further balance the conditions, there is an extraction of the gas given off by the magnetrons that are not in the operating position via the suction openings (443) in the enclosure. The pressure conditions in the enclosure correspond to those in the vacuum chamber because of that. The gas extraction takes place through suction openings (443) that have not been put into the wall opposite the magnetron, but instead into the walls arranged on the side of that. The gas flow that is to also be expected in the operating position, where the gas extraction of the vacuum chamber leads to a gas flow past the side of the substrate, is emulated in this way.

### LIST OF REFERENCE NUMERALS

1 Vacuum chamber
11 Air lock
111 Slide unit of the air lock to the vacuum chamber
112 Slide unit of the air lock to the environment
113 Gas exhaust system of the air lock
114 Gas exhaust system (vacuum creation) of the vacuum chamber
115 Lifting device to lift the workpiece
2 Transport device with main axis
21 Suspension element
22 Vacuum-tight enclosure of the internal motor of the suspension element
3a Workpiece in the air lock
3b Workpiece after the lifting movement into the vacuum chamber on the transport device
3c Workpiece during the processing in motion and rotation
3d Workpiece on the roller device before intake through the air lock
3e Workpiece before the lifting movement in the vacuum chamber
3f Rotary movement of the workpiece
31 Axis of rotation around which the workpiece is rotated during processing
32 Surface of the workpiece to be processed
33 Lifting movement of the workpiece during intake through the air lock
34 Particle flow from the magnetron to the workpiece
4 Magnetron drum
41 Individual magnetron
42 Axis of rotation of the magnetron drum
43 Aperture
431 Opening of the aperture
44 Enclosure of the magnetron drum
441 Cover of the operating opening of the enclosure of the magnetron drum
442 Operating opening of the enclosure of the magnetron drum
443 Gas suction openings in the enclosure
45 Magnetron in the operating position
46 Match box for high-frequency adaptation of the magnetron
5 Roller device to transport the workpiece
6 Ion source
7 Supply unit
71 Bellow-type membrane seal
72 Carrier device of the supply unit outside of the vacuum chamber
73 Drive device of the supply unit
74 Reinforcement system for a defined and precise arrangement of the main axis and the magnetron drum with respect to one another
741 Reinforcement part
742 Holder of the magnetron drum
A Distance of the magnetrons that are not in the operating position to the enclosure
B Distance of the magnetron in the operating position to the substrate

1. Device for processing surfaces that has a vacuum chamber with
a transport device with a main axis of motion and accommodations for at least one workpiece,
a rotatable carrier drum with at least two processing devices arranged on it that are surrounded by an enclosure that has an opening for the workpiece,
wherein at least one processing device is aligned in an operating position with respect to the workpiece in the opening of the enclosure, characterized in that the distance from the processing device to the surface to be processed in the operating position is approximately equal to the distance from the processing device or processing devices that are not in the operating position to the enclosure.

2. (canceled)

3. Device according to claim 1, characterized in that the carrier drum has similar or different processing devices which are magnetrons and/or ion-beam sources and/or plasma sources and/or sputtering sources and/or activation sources and/or pulsed-laser deposition sources and/or optical observation devices and/or spectroscopes and/or laser-beam sources.

4. Device according to claim 1, characterized in that the axis of rotation of the carrier drum is arranged horizontally or vertically.

5. Device according to claim 4, characterized in that the processing devices are rod-shaped magnetrons that are suitable for coating the workpiece over the entire width of the substrate.

6. Device according to claim 1, characterized in that the opening in front of the processing device in the operating position can be closed.

7. (canceled)

8. Device according to claim 1, characterized in that the processing devices are round magnetrons and in that the magnetron in the operating position is released by an aperture via rotation of the magnetron drum and/or the aperture.

9. Device according to claim 1, characterized in that the enclosure has a gas exhaust system and/or a gas supply system.

10. Device according to claim 9, characterized in that the gas exhaust system is suitable for bringing about the same gas flow for processing devices that are not in the operating position that exists for the processing device in the operating position.

11. Device according to claim 1, characterized in that a device for carrying out lifting, lowering or advancing movements is provided to transfer the workpiece from an air lock to the transport device or from the transport device to an air lock.

12. Device according to claim 1, characterized in that sensors are provided that are suitable for detecting the condition and operating state of the magnetron and of the workpiece and for forwarding this information along in a wireless or wired fashion to a data-processing system, wherein the data-processing system is suitable for controlling both the movement and rotation of the workpiece, as well as the positioning and, if applicable, the replacement of target material or magnetrons.

13. Method for processing surfaces of a workpiece in a device according to claim 1, wherein at least the following steps are carried out:
a) holding the workpiece in the transport device,
b) rotating the carrier drum until the processing device to be used reaches the operating position and becomes the active processing device,
c) moving the workpiece along the main axis at a slight distance to the active processing device, wherein a first processing technology is applied to the workpiece,
d) repeating the steps b) and c) until the intended surface condition is achieved.

14. Method according to claim 13, characterized in that the workpiece is moved via an air lock into the vacuum chamber before step 13a) and is moved via an air lock out of it after step 13d).

15. Method according to claim 13, characterized in that step 13.c) is carried out several times one after the other with a reversed direction of motion along the main axis in each case.

16. Method according to claim 13, characterized in that step 13.c) is performed with a variable movement speed.

17. Method according to claim 13, characterized in that step 13.c) is carried out with a variable movement height over the processing device in the operating position.

18. Method according to claim 13, characterized in that the workpiece rotates, at least during step 13.c), in a plane perpendicular to the shortest connection of the main axis and the processing device in the operating position.

19. Method according to claim 13, characterized in that the processing devices are magnetrons.

20. Method according to claim 19, characterized in that the target material and/or a magnetron is replaced in situ during the operation of a different magnetron in the operating position.

21. Method according to claim 19, characterized in that magnetrons that are not in the operating position are also started up.

22. Use of the method according to claim 13 to apply several coating layers to a substrate.
